(19) United States
(12) Patent Application Publication
(10) Pub. No.: US 2010/0141280 A1
(43) Pub. Date: Jun. 10, 2010

(54) BIOSENSOR READER AND BIOSENSOR READER SYSTEM

(75) Inventors: Jong-Heon YANG, Daejeon (KR); Taeyoub KIM, Seoul (KR); Ansoon KIM, Daejeon (KR); Chan Woo PARK, Daejeon (KR); In Bok BAEK, Cheongju-si (KR); Chil Seong AH, Daejeon (KR); Chang-Geun AHN, Daejeon (KR); Gun Yong SUNG, Daejeon (KR); Seon Hee PARK, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunications Research Institute, Daejeon (KR)

(21) Appl. No.: 12/567,123

(22) Filed: Sep. 25, 2009

(30) Foreign Application Priority Data
Dec. 5, 2008 (KR) 10-2008-0123235
Apr. 10, 2009 (KR) 10-2009-0031275

(51) Int. Cl. G01R 27/08

(52) U.S. Cl. 324/692

(57) ABSTRACT

A biosensor reader and a biosensor reader system are provided. The biosensor reader has a field-effect transistor (FET) biosensor attached thereto, and the FET biosensor includes between electrodes a probe channel to which probe materials are immobilized. The biosensor reader analyzes an electrical conductivity change of the probe channel caused by the binding between the probe material and a target material contained in an analysis solution. The biosensor reader includes a measurement module and an output module. The measurement module connects the probe channel electrically to a reference resistance with a fixed resistance value by the attachment of the FET biosensor, measures a reference voltage drop across the reference resistance and a channel voltage drop across the probe channel, and analyzes an electrical conductivity change of the probe channel from the reference voltage drop and the channel voltage drop. The output module outputs the analysis result of the target material according to the electrical conductivity change.

### CROSS-REFERENCE TO RELATED APPLICATIONS

This U.S. non-provisional patent application claims priority under 35 U.S.C. §119 of Korean Patent Application Nos. 10-2008-0123235, filed on Dec. 5, 2008, and 10-2009-0031275, filed on Apr. 10, 2009, the entire contents of which are hereby incorporated by reference.

### BACKGROUND OF THE INVENTION

The present invention disclosed herein relates to a biosensor reader and a biosensor reader system, and more particularly, to a biosensor reader and a biosensor reader system that use a field-effect transistor (FET) biosensor to analyze biomaterials.

Biosensors are devices capable of detecting an optical or electrical signal that varies with the selective reaction and binding between a probe material and a specific target material contained in a biomaterial such as blood and urine. Thus, biosensors are used to detect the presence of biomaterials or to analyze biomaterials qualitatively or quantitatively.

Biosensors may detect signals by various physicochemical methods such as colors of analytes, fluorescence, electrical signals, and optical signals.

For example, a strip-type rapid kit performs signal conversion by a simple color method because it only determines if there are biomarkers more than a predetermined threshold concentration.

In the case of an FET biosensor detecting a target material by an electrical signal, a target material binds to a very small wire-type or thin film-type semiconductor structure, the electrical conductivity of the semiconductor structure changes by the target material, and the target material is detected through an electrical conductivity change.

If an electrochemical reaction occurs at the binding of the target material or if the target material has an electric charge, the electrons or holes of the semiconductor structure are accumulated or depleted due to an electric field effect caused by the binding between the target material and a probe material, which is measured as an electrical conductivity change. However, an analysis system using such an FET biosensor has low reproducibility and requires a long analysis time and an expensive equipment for system implementation because it is huge and requires an expensive and accurate measurement equipment and a manual measurement process.

In the case of blood sugar, glycosuria or blood pressure, the concentration must be periodically measured or a relapse of a disease must be periodically observed after remedy. In this case, high-sensitivity measurement of a small amount of biomaterial present in body fluid is required. What is therefore required is a biosensor reader that has a measurement function, an analysis function, and a result display function.

### SUMMARY OF THE INVENTION

The present invention provides a miniaturized biosensor reader that can analyze biomaterials with a high sensitivity by means of an FET biosensor.

The present invention also provides a biosensor reader system that can analyze biomaterials with a high sensitivity by means of an FET biosensor.

The objects of the present invention are not limited to the aforesaid, and other objects not described herein will be clearly understood by those skilled in the art from descriptions below.

Embodiments of the present invention provide biosensor readers that have an FET biosensor, which includes between electrodes a probe channel to which probe materials are immobilized, attached thereto and analyze an electrical conductivity change of the probe channel caused by the binding between the probe material and a target material contained in an analysis solution. The biosensor readers include: a measurement module connecting the probe channel electrically to a reference resistance with a fixed resistance value by the attachment of the FET biosensor, measuring a reference voltage drop across the reference resistance and a channel voltage drop across the probe channel, and analyzing an electrical conductivity change of the probe channel from the reference voltage drop and the channel voltage drop; and an output module outputting the analysis result of the target material according to the electrical conductivity change.

In other embodiments of the present invention, biosensor reader systems have an FET biosensor, which includes between electrodes a probe channel to which probe materials are immobilized, attached thereto and analyze an electrical conductivity change of the probe channel caused by the binding between the probe material and a target material contained in an analysis solution. The biosensor reader systems include: a measurement unit measuring a channel voltage drop across the probe channel of the FET biosensor, whose resistance value varies by the binding between the target material and the probe material, and a reference voltage drop across a reference resistance with a fixed resistance value, and outputting a measurement signal according to a difference between the channel voltage drop and the reference voltage drop; a signal processing unit analyzing the target material from the measurement signal; and an output unit outputting the signal process result of the signal processing unit.

The details of other embodiments are included in the detailed description and the drawings.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a perspective view of a biosensor for a biosensor reader according to an exemplary embodiment of the present invention;

FIG. 2 is an exploded perspective view of a biosensor reader according to an exemplary embodiment of the present invention;

FIG. 3 is a perspective view of a display module in the biosensor reader according to an exemplary embodiment of the present invention;

FIG. 4 is an exploded perspective view of a measurement module in the biosensor reader according to an exemplary embodiment of the present invention;

FIG. 5 is an exploded perspective view of a pump module in the biosensor reader according to an exemplary embodiment of the present invention;

FIG. 6 is a diagram illustrating the connection between the respective modules in the biosensor reader according to an exemplary embodiment of the present invention;

FIG. 7 is a graph illustrating an electrical conductivity change in the biosensor when a biomaterial is analyzed using the biosensor reader according to an embodiment of the present invention;

FIG. 8 is a block diagram of a biosensor reader system according to an exemplary embodiment of the present invention;

FIG. 9 is a block diagram of an input signal generating unit in a measurement unit of the biosensor reader system according to an exemplary embodiment of the present invention;

FIG. 10 is a block diagram of an analog circuit unit in the measurement unit of the biosensor reader system according to an exemplary embodiment of the present invention;

FIG. 11 is a block diagram of a back-bias voltage generating unit in the measurement unit of the biosensor reader system according to an exemplary embodiment of the present invention;

FIGS. 12A to 12C are diagrams illustrating the electrical connection between a reference resistance and a probe channel in the measurement unit of the biosensor reader system according to an exemplary embodiment of the present invention; and

FIG. 13 is a graph illustrating the output waveform outputted from the measurement unit in accordance with the channel resistance of a biosensor in the biosensor reader system according to an exemplary embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout the specification.

In the following description, the technical terms are used only for explaining specific exemplary embodiments while not limiting the present invention. The terms of a singular form may include plural forms unless otherwise specified. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiments in the detailed description will be described with reference to sectional views or plan views as ideal exemplary views of the present invention. In the drawings, the dimensions of layers and regions are exaggerated for clarity of illustration. Areas exemplified in the drawings have general properties, and are used to illustrate specific shapes of device regions. Thus, these should not be construed as limiting to the scope of the present invention.

In the specification, target materials are biomaterials with specific natures, which are interpreted as having the same meaning as assays or analytes. In an exemplary embodiment, the biomaterial may be an antigen.

In the specification, probe materials are biomaterials binding specifically to target materials, which are interpreted as having the same meaning as receptors or acceptors. In an exemplary embodiment, the probe material may be an antibody.

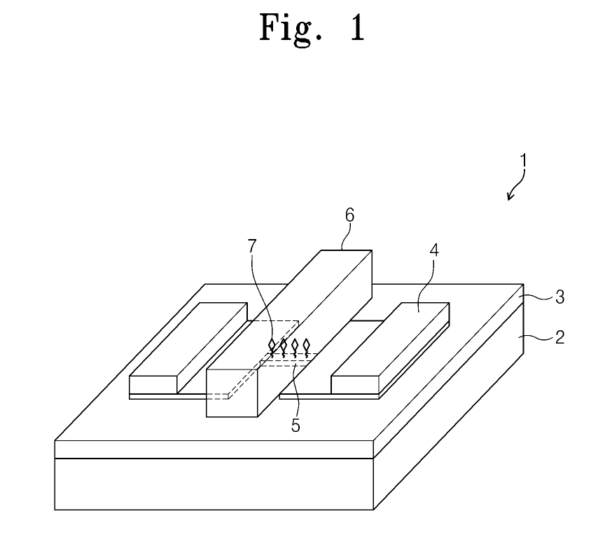

Hereinafter, a biosensor reader according to an exemplary embodiment of the present invention will be described in detail with reference to the accompanying drawings. First, a biosensor of a biosensor reader according to an exemplary embodiment of the present invention will be described in detail with reference to FIG. 1.

FIG. 1 is a perspective view of a biosensor attached to a biosensor reader according to an exemplary embodiment of the present invention.

The biosensor attached to the biosensor reader may be a FET biosensor that is fabricated through a semiconductor process to have a small size. The biosensor may be cartridge-shaped or chip-shaped.

Referring to FIG. 1, a FET biosensor 1 according to an exemplary embodiment of the present invention includes a support substrate 2, a dielectric layer 3, source/drain electrodes 4, a probe channel 5, and a fluid channel 6.

The support substrate 2 may be a bulk semiconductor substrate, and the dielectric layer 3 is disposed on the support substrate 2. That is, the biosensor is formed on a silicon-on-insulator (SOI) substrate in order to reduce a leakage current and increase a driving current.

The source/drain electrodes 4 are disposed on the dielectric layer 3 such that they are spaced apart from each other by a predetermined distance. The source/drain electrodes 4 are connected to the biosensor reader so that a predetermined voltage may be applied to the source/drain electrodes 4. The probe channel 5 is formed between the source/drain electrodes 4.

The probe channel 5 is a region where probe materials and target materials may bind together. The probe channel 5 may be formed of a material whose electrical characteristics change according to an external electric field. For example, the probe channel 5 may include crystalline silicon, amorphous silicon, a doped layer, a semiconductor layer, an oxide layer, a compound layer, a carbon nano tube (CNT), or a semiconductor nanowire. In exemplary embodiments of the present invention, the probe channel 5 may be a doped layer that is formed by diffusion of n-type or p-type impurities. The probe channel 5 including a doped layer may be formed to a nano size in order to improve the sensitivity of the biosensor. Also, the probe channel 5 including a doped layer extends to the bottoms of the source/drain electrodes 4 so that the doped layer may be in ohmic contact with the source/drain electrodes 4.

Probe materials 7, which bind specifically to a specific target material present in analysis solution, are immobilized on the surface of the probe channel 5. The probe materials 7 may be immobilized on the surface of the probe channel 5 directly or using a linker as an intermediate medium.

The fluid channel 6, through which analysis solution flows, may be formed on the probe channel 5 that has the probe materials 7 immobilized thereon. That is, the fluid channel 6 is configured to provide analysis solution containing target materials to the probe channel 5. For example, the analysis solution may be physiological body fluid such as blood, plasma, serum, interstitial fluid, lavage, perspiration, saliva, and urine. The fluid channel 6 may have a micro diameter to provide a capillary force. Thus, the analysis solution may flow through the fluid channel 6 by the capillary force.

The electrical conductivity of the biosensor 1 changes according to the charge quantity of a biomaterial that generates an electric field effect on the surface of the probe channel 5. That is, the electrical conductivity of the biosensor 1 changes by the binding between the probe material and the target material on the surface of the probe channel 5.

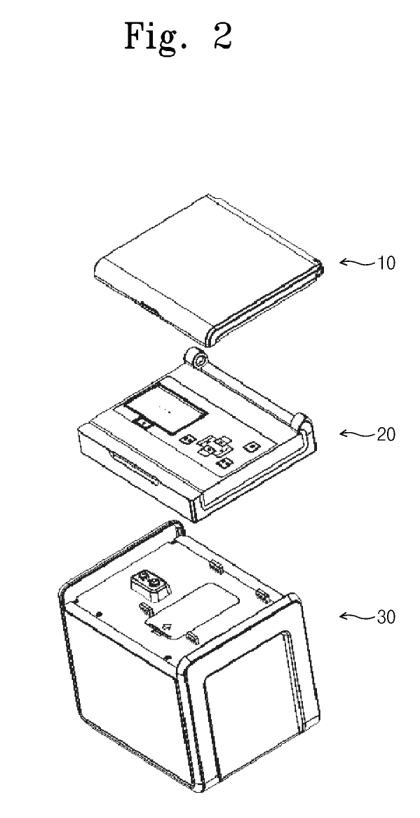

FIG. 2 is an exploded perspective view of a biosensor reader according to an exemplary embodiment of the present invention.

Referring to FIG. 2, the biosensor reader includes a display module 10, a measurement module 20, and a pump module 30.

The display module 10 may be a top cover of the biosensor reader. The display module 10 displays an electrical signal detected from an FET biosensor and the analysis results of the electrical signal to a user. The display module 10 may be substantially a cover of the measurement module 20. The display module 10 may include a liquid crystal display (LCD) or a touchscreen. That is, the display module 10 may include an interface to receive commands from the user.

The measurement module 20 is electrically connected to an attached FET biosensor to measure the electrical conductivity from the FET biosensor. On the top of the measurement module 20, an attachment unit 20a is provided to attach/detach the FET biosensor and an input unit 20b is provided to input user commands. Also, the measurement module 20 includes a battery, a power supply circuit, an analog circuit for measuring the electrical conductivity, a digital circuit for controlling the biosensor reader and analyzing the electrical conductivity, and an interface circuit for inputting/outputting user commands.

The pump module 30 supplies/discharges analysis solutions to/from an FET biosensor attached to the measurement module 20. The pump module 30 has an inlet for supplying analysis solutions to the FET biosensor, and an outlet for discharging analysis solutions that have passed through the FET biosensor. Also, the pump module 30 may have storage containers for storing analysis solutions necessary for analysis of biomaterials, and syringe pumps for circulating analysis solutions smoothly.

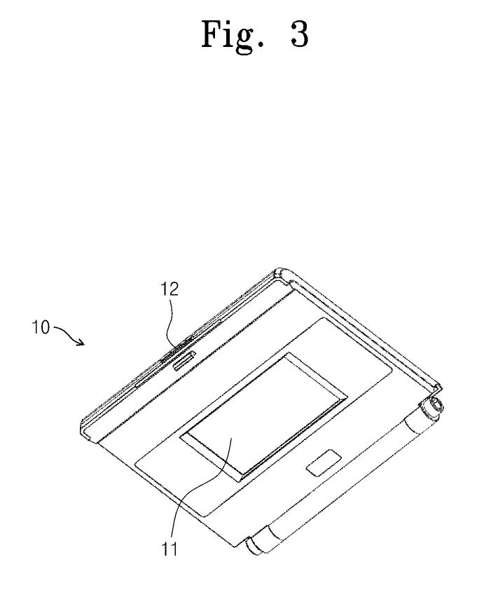

FIG. 3 is a perspective view of the display module 10 in the biosensor reader according to an exemplary embodiment of the present invention.

Referring to FIG. 3, the display module 10 displays the measurement results of the measurement module 20 and the analysis results of a biomaterial. An LCD 11 is installed on the plane of the display module 10, and the display module 10 may receive user commands through a touchscreen. Also, the display module 10 may have input units for receiving user commands on behalf of the touchscreen. Also, the display module 10 serves as a cover of the biosensor reader, and may have an open/close switch 12 for opening/closing the display module 10.

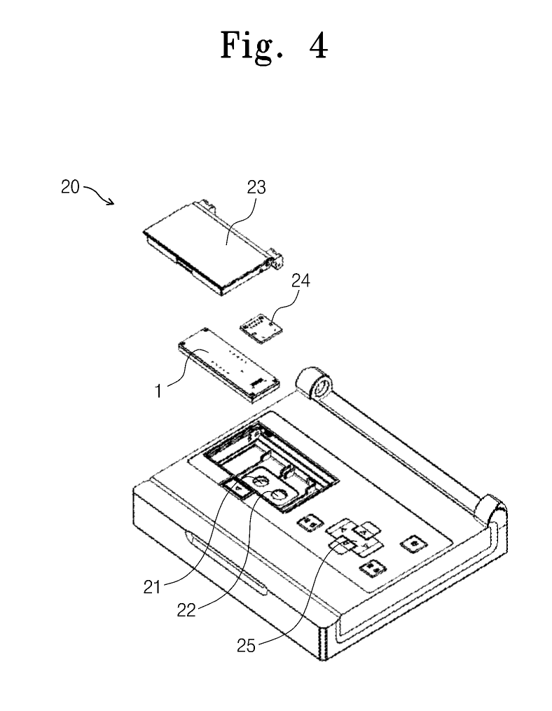

FIG. 4 is an exploded perspective view of the measurement module 20 in the biosensor reader according to an exemplary embodiment of the present invention.

Referring to FIG. 4, the attachment unit of the measurement module 20 may include a groove that has substantially the same size as the biosensor 1 to fix the biosensor 1 therein. The attachment unit may have holes 21 and 22 formed to connect the pump module 30 (see FIG. 2) and the biosensor 1. That is, an inlet 21 may be formed to supply analysis solutions and an outlet 22 may be formed to discharge the analysis solutions.

A cover unit 23 covering the biosensor 1 is provided on the attachment unit of the measurement module 20, and a printed circuit board (PCB) 24 connected electrically to the biosensor 1 is attached to the cover unit 23. In order to prevent the leakage of an analysis solution, when the cover unit 23 is closed, a suitable force is applied by a spring or a damper to the biosensor 1 so that the biosensor 1 may adhere closely to the inlet 21 and the outlet 22. Also, when the cover unit 23 is closed, the PCB 24 contacts the electrodes formed in the biosensor 1. That is, an input signal for analysis of a biomaterial is applied through the PCB 24 to the biosensor 1, and an electrical conductivity change depending on the biomaterial may be measured.

The measurement module 20 may have an open/close switch 25 for opening/closing the cover unit 23, and a tact switch for making it possible to detect the accurate attachment of the biosensor 1 to the measurement module 20 when the cover unit 23 is closed.

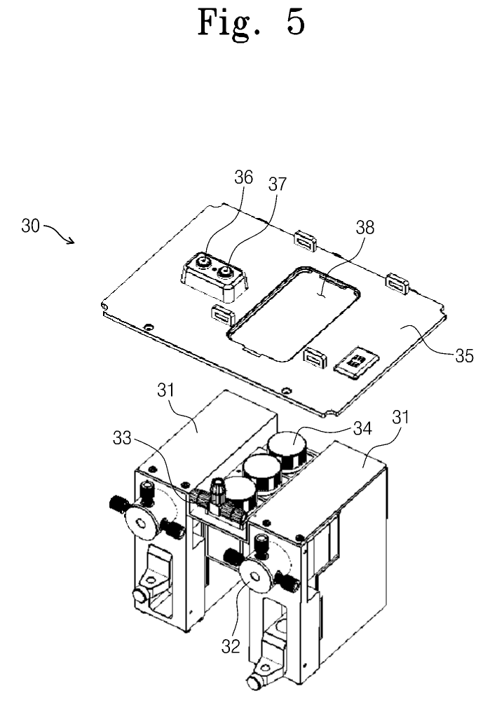

FIG. 5 is an exploded perspective view of the pump module 30 in the biosensor reader according to an exemplary embodiment of the present invention.

Referring to FIG. 5, the pump module 30 includes syringe pumps 31 for supplying/discharging analysis solutions, and storage containers 34 for storing the analysis solutions. A top case 35 of the pump module 30 has an analysis solution inlet 36 and an outlet 37 at the position corresponding to the attachment unit of the measurement module 20 (see FIG. 4). Also, the top case 35 of the pump module 30 may have an opening 38 for replacing the storage containers 34 by new ones.

The syringe pump 31 may be provided in plurality corresponding to the analysis solutions supplied to the biosensor 1. For example, the pump module 30 may include: a syringe pump 31 for supplying an analysis solution containing target materials (i.e., biomaterials to be analyzed); a syringe pump 31 for supplying a buffer solution used to wash out the analysis solution and measure the electrical conductivity change before/after the antibody-antigen reaction; and a syringe pump 31 for discharging a waste solution.

A distribution port 32, a tee connector 33, and a tube (not shown) are connected to the syringe pump 31, so that the biosensor 1 may be connected to the storage container 34 storing analysis solutions.

That is, analysis solutions supplied through the distribution port 32 from the respective syringe pumps 31 may be mixed through the tee connector 33, and the analysis solutions mixed through the tee connector 33 may flow through the tube to the inlet 36. A waste solution, which has passed through the biosensor 1, may be discharged to the waste solution storage container 34 through the tube connected to the outlet 37.

The tubes in the pump module 30 may have a small diameter of about 1/16 inch. Accordingly, the amount of analysis solution filling the tube can be reduced, and the analysis solution can be rapidly supplied. Also, the length of the tube may be minimized to reduce the noise in the measurement of the electrical conductivity of the biosensor 1.

It has been described that the biosensor reader according to the embodiment of the present invention has the pump module. However, the biosensor reader may not have the pump module. If the biosensor reader does not have the pump module, the analysis solution may be supplied directly to the biosensor of the measurement module.

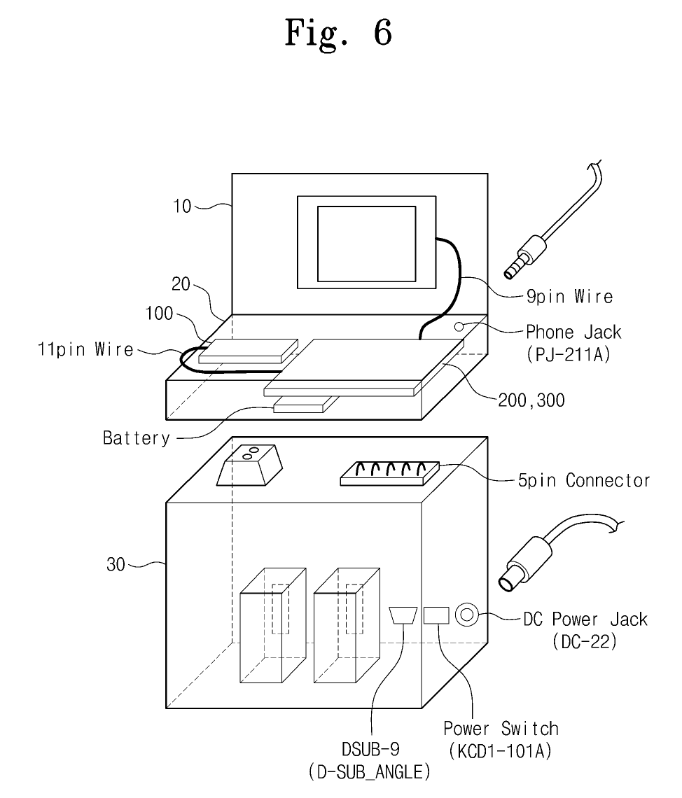

FIG. 6 is a diagram illustrating the connection between the respective modules in the biosensor reader according to an exemplary embodiment of the present invention.

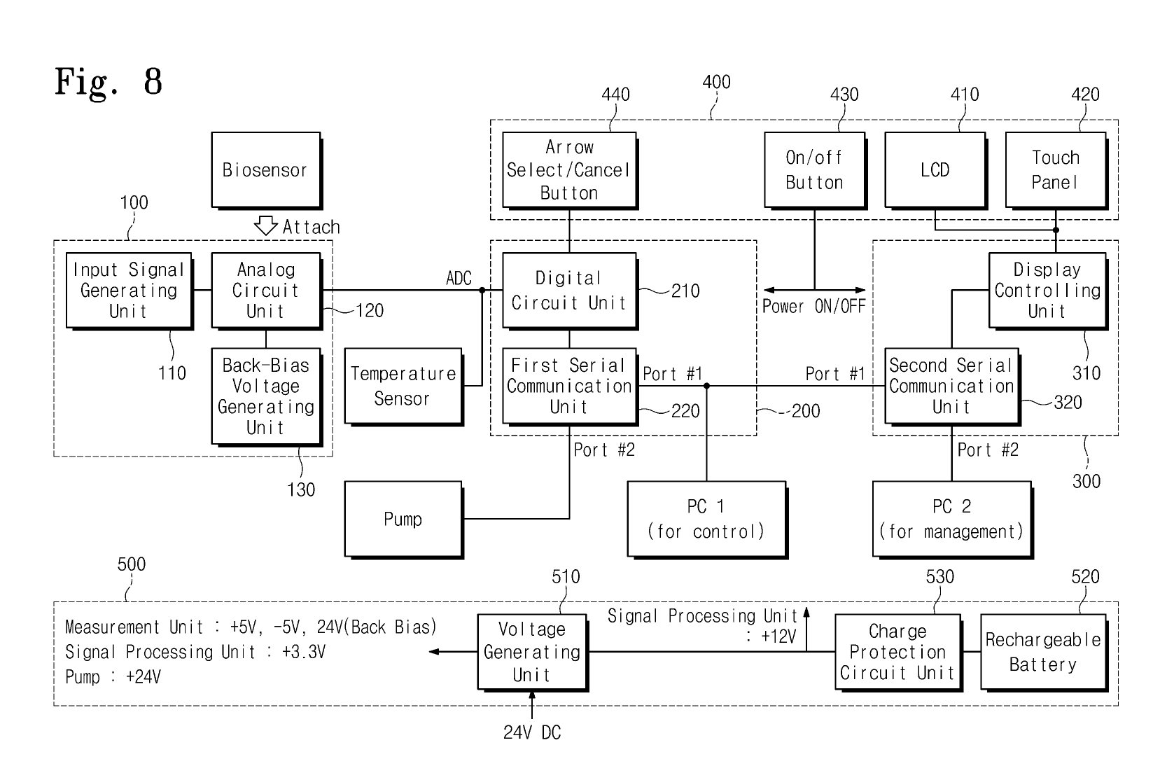

Referring to FIG. 6, the display module 10 and the measurement module 20 of the biosensor reader may be connected through a 9-pin wire. The PCB of the measurement module 20 (see 100 of FIG. 8) and a signal processing circuit (see 200 and 300 of FIG. 8) may be connected through an 11-pin wire. Herein, the signal processing circuit may include a power supply circuit, an analog circuit for measuring the electrical conductivity, a digital circuit for controlling the biosensor reader and analyzing the electrical conductivity, and an interface circuit for inputting/outputting user commands. Also, 8 pins of the 11-pin wire may be connected to the electrodes of the biosensor; 1 pin may be connected to the substrate of the biosensor; and 2 pins may be connected to the switches for a biosensor attachment check. Also, a battery may be provided in the measurement module 20 in order to miniaturize the biosensor reader and facilitate the portability of the biosensor reader.

A user's personal computer (PC) for controlling the display module 10 and the measurement module 20 may be connected through a phone jack to the biosensor reader.

The measurement module 10 and the pump module 30 may be connected through a 5-pin connector that includes an RX pin, a TX pin, a PCB signal ground pin, a back-bias 24-V pin, a power ground pin. Also, the pump module 30 may have a DC power jack, a power on/off switch, and a DSUB-9 port for serial communication between the pump module 30 and the user.

Hereinafter, a method for analyzing a biomaterial by means of the biosensor reader according to an exemplary embodiment of the present invention will be described with reference to FIGS. 2 to 7.

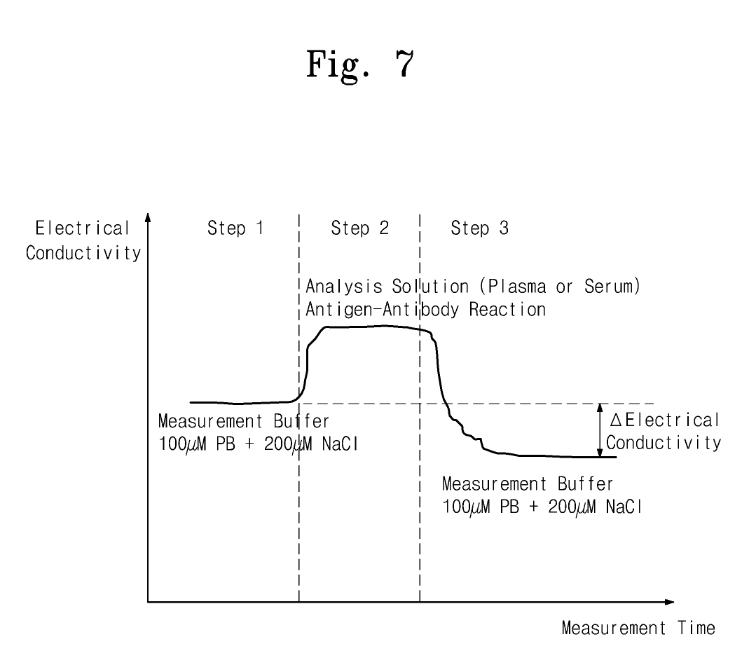

FIG. 7 is a graph illustrating an electrical conductivity change in the biosensor when a biomaterial is analyzed using the biosensor reader according to an embodiment of the present invention. Specifically, FIG. 7 illustrates an electrical conductivity change in the biosensor when an antigen concentration is measured using an antigen-antibody reaction.

The electrical conductivity of the FET biosensor changes according to the charge quantity of the target material and the probe material transferring an electric field effect to the probe channel. Therefore, if the ion concentration of the analysis solution is high, the electric field effect generated by the target material and the probe material is not transferred to the probe channel due to the charge screening of the biomaterial. Therefore, the ion concentration of the analysis solution provided to the probe channel must be low in order to measure an electrical conductivity change caused by the electric field effect.

Thus, through the following steps, the concentration of the target material may be detected by analyzing an electrical conductivity variation when the buffer solution with a low ion concentration is supplied before/after the analysis solution with a high ion concentration is supplied to the probe channel of the FET biosensor.

In step 1, the electrical conductivity of the biosensor is measured before the target material and the probe material bind together. That is, in step 1, the electrical conductivity of the probe channel is measured before the target material and the probe material bind together. Specifically, the electrical conductivity of the biosensor is measured when the buffer solution with a low ion concentration is supplied to the probe channel of the biosensor. In an exemplary embodiment of the present invention, a liquid mixture of about 100 μM PB (phosphate buffer) and about 200 μM NaCl is used as the buffer solution.

In step 2, the analysis solution is supplied to bind the target material and the probe material. That is, the electrical conductivity of the biosensor is measured when plasma or serum containing an antigen is supplied to the probe channel. Herein, because body fluid such as serum or plasma has a high ion concentration, the antigen and the antibody may be bound tightly.

In step 3, the electrical conductivity of the probe channel is measured when the target material and the probe material bind together. Specifically, the body fluid with a high ion concentration is removed by supplying the buffer solution to the probe channel, and the electrical conductivity of the probe channel is measured when the target material and the probe material bind together. Due to the binding of the target material and the probe material, the electrical conductivity measured in step 3 may be lower than the electrical conductivity measured in step 1.

Thereafter, a difference between the electrical conductivity measured in step 1 and the electrical conductivity measured in step 3 is calculated. That is, an electrical conductivity variation before/after the antigen-antibody reaction is calculated, and the electrical conductivity variation is compared and analyzed with respect to a library file to calculate the concentration of the antigen. Herein, the library file has data obtained from the electrical conductivity changes by the binding of antibodies and antigens whose concentrations are well known.

When the biosensor reader is used to analyze the biomaterial, the pump module 30 may be driven by one syringe pump 31. If one syringe pump is used, the distribution port 32 with four or more branches may be used.

In step 1, the syringe pump 31 inhales the buffer solution and supplies the inhaled buffer solution to the probe channel of the FET biosensor. In step 2, the syringe pump 31 inhales the analysis solution containing the target material and supplies the inhaled analysis solution to the probe channel of the FET biosensor. In step 3, the syringe pump 31 inhales the buffer solution again and supplies the inhaled buffer solution to the probe channel of the FET biosensor.

In the syringe pump 31, the supply flow rates of the analysis solution and the buffer solution may vary depending on the syringe capacity. Also, the driving of the syringe pump 31 may be controlled by a PC or the biosensor reader.

Hereinafter, a biosensor reader system according to an exemplary embodiment of the present invention will be described in detail with reference to the accompanying drawings.

FIG. 8 is a block diagram of a biosensor reader system according to an exemplary embodiment of the present invention.

Referring to FIG. 8, the biosensor reader system includes a measurement unit 100, a signal processing unit 200, a signal displaying unit 300, an interface unit 400, and a power supply unit 500.

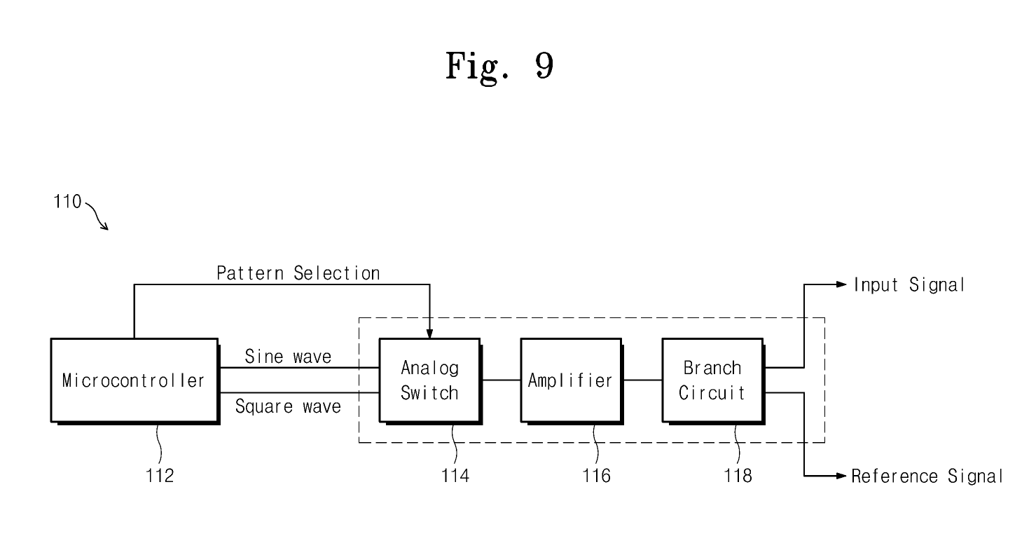

The measurement unit 100 measures an electrical conductivity of an analog signal from a biosensor. The measurement unit 100 includes: an input signal generating unit 110 generating and applying an input signal to the biosensor; an analog circuit unit 120 connected electrically to the attached biosensor to detect an electrical conductivity change; and a back-bias voltage generating unit 130 applying a predetermined DC voltage, generated from a power supply voltage, to a substrate of the biosensor. A measurement signal outputted from the analog circuit unit 120 is processed through an analog-to-digital converter (ADC) prior to transmission to the signal processing unit 200. The measurement unit 100 will be described later in detail with reference to FIGS. 9 to 11.

The signal processing unit 200 includes a digital circuit unit 210 and a first serial communication unit 220. The digital circuit unit 210 extracts data from a measurement signal measured by the biosensor, and compares and analyzes the data with respect to a library file to calculate the concentration of a biomaterial. Also, the digital circuit unit 210 receives a command signal from the interface unit 400.

The first serial communication unit 220 is provided to transmit measurement data to an external PC and set the biosensor reader system. That is, the first serial communication unit 220 transmits an analysis signal, outputted from the digital circuit unit 210, to a pump and the signal displaying unit 300. The pump connected to the first serial communication unit 220 may be controlled according to the analysis signal of a biomaterial outputted from the digital circuit unit 210 or the command signal received from the interface unit 400.

The signal processing unit 200 may be an embedded system board including a signal processing unit, an external communication unit, a data storage unit, and a library file for analysis of a biomaterial. For example, a memory card for storage of output signal data is inserted in the embedded system board; and a system OS, a driving program for measurement of the electrical conductivity, and a library file for analysis of the biomaterial are stored in the memory card. Also, the signal processing for analysis of the concentration of the biomaterial is performed through the comparison/analysis with respect to the library file in a CPU of the embedded system board, and the analysis results are stored in the memory card.

The signal displaying unit 300 includes a display controlling unit 310 and a second serial communication unit 320. The display controlling unit 310 displays the biomaterial analysis process or the biomaterial analysis result through the interface unit 400. Also, the display controlling unit 310 receives user commands from the interface unit 400, provides feedback signals for the user commands to the interface unit 400, and transfers the user commands. The signal displaying unit 300 may be connected through the second serial communication unit 320 to a user's PC, so that a biomaterial analysis environment and a library update may be provided through the user's PC.

The interface unit 400 includes an LCD 410, a touch panel 420, and operation buttons 430 and 440. The interface unit 400 may be configured using an embedded system board with a touchscreen display, and a program considering the user's convenience is created to display the detected analysis results. The embedded system board has its own CPU, drives an OS, and controls the touchscreen display. The operation buttons 430 and 440 of the interface unit 400 may be used to turn on/off the operation of the biosensor reader, and may be connected to the signal processing unit 200 to control the signal processing unit 200 according to user commands. That is, biomaterial analysis is started when the corresponding user command is inputted through the interface unit 400. Herein, the interface unit 400 displays the analysis process during the biomaterial analysis and displays the analysis result (e.g., the concentration of the biomaterial) after the end of the biomaterial analysis.

The power supply unit 500 includes an internal voltage generating unit 510 that receives an external power supply voltage (e.g., about 24 V DC) to provide driving voltages to the measurement unit 100, the signal processing unit 200, and the signal displaying unit 300. For example, the voltage generating unit 510 provides a driving voltage (e.g., about ±5 V) for driving of the measurement unit 100, a back-bias voltage (e.g., about +24 V) of the biosensor, a driving voltage (e.g., about +3.3 V) for driving of the signal processing unit 200, and a driving voltage (e.g., about +12 V) for driving of the signal displaying unit 300. Also, the voltage generating unit 510 may provide a pump driving voltage (e.g., about 24 V). Also, for implementation of a portable biosensor reader, the power supply unit 500 may include a portable (or rechargeable) battery 520 and a charge protection circuit unit 530 for charging/protecting the battery 520. Also, the voltage generating unit 510 may provide a power supply voltage to the battery to charge the battery.

Hereinafter, the measurement unit 100 in the biosensor reader system will be described in detail with reference to FIGS. 9 to 11.

FIG. 9 is a block diagram of the input signal generating unit 110 in the measurement unit 100 of the biosensor reader system according to an exemplary embodiment of the present invention.

Referring to FIG. 9, the input signal generating unit 110 includes a microcontroller 112, an analog switch 114, an amplifier 116, and a branch circuit 118.

The microcontroller 112 generates signals of various waveforms such as a sine wave, a pulse wave, and a DC voltage. The sine wave may be generated by a digital-to-analog converter (DAC) in the microcontroller 112, and the pulse wave may be generated by a digital output signal of ‘1 ’ and ‘0 ’. For example, a sine wave of several V may be generated by the DAC, and a sine wave of tens of V may be obtained through the amplifier 116 with a voltage gain of about 1/100. In an exemplary embodiment of the present invention, the input signal generating unit 110 generates an input signal of about 10 mV to about 1 V in order not to affect the lifetime of a biomaterial.

The analog switch 114 selects one of the waveforms generated by the microcontroller 112 and transfers the selected waveform to the amplifier 116. The amplifier 116 amplifies the selected waveform, and the branch circuit 118 branches the amplified waveform into an input signal of the analog circuit unit 120 and a reference signal of a phase compensation circuit of the analog circuit unit 120.

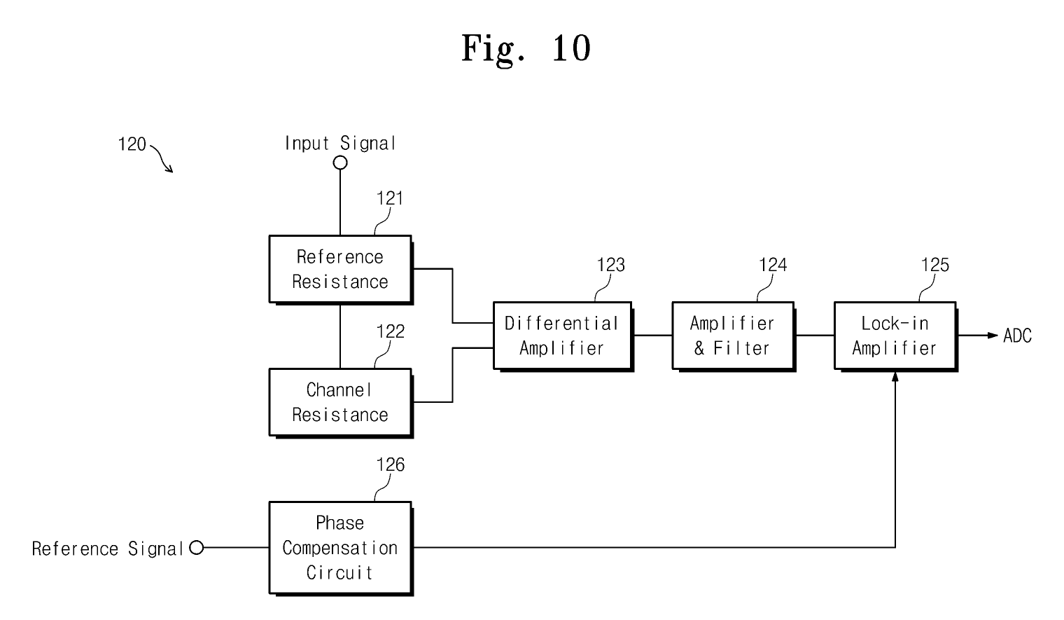

FIG. 10 is a block diagram of the analog circuit unit 120 in the measurement unit 100 of the biosensor reader system according to an exemplary embodiment of the present invention.

Referring to FIG. 10, the analog circuit unit 120 includes a reference resistance 121, a channel resistance 122, a differential amplifier 123, an amplifier/filter 124, a lock-in amplifier 125, and a phase compensation circuit 126.

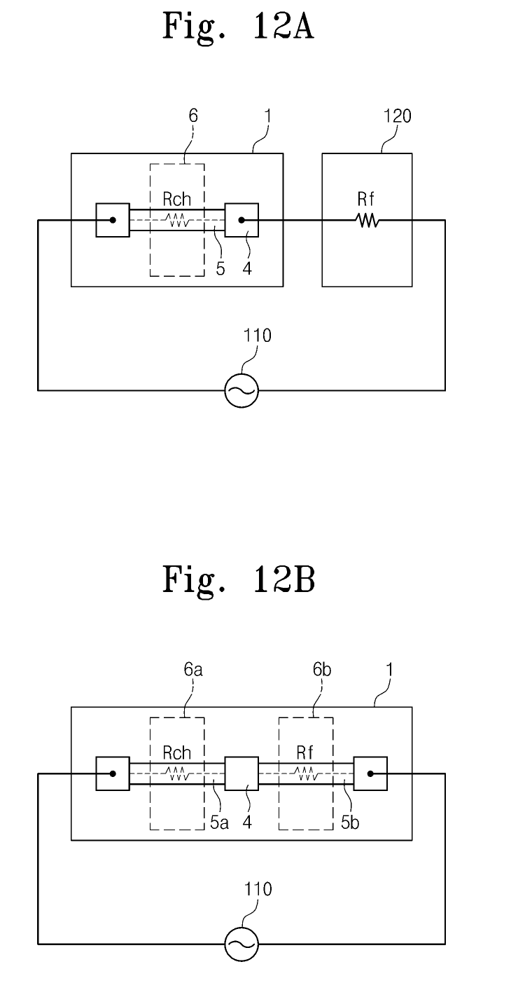

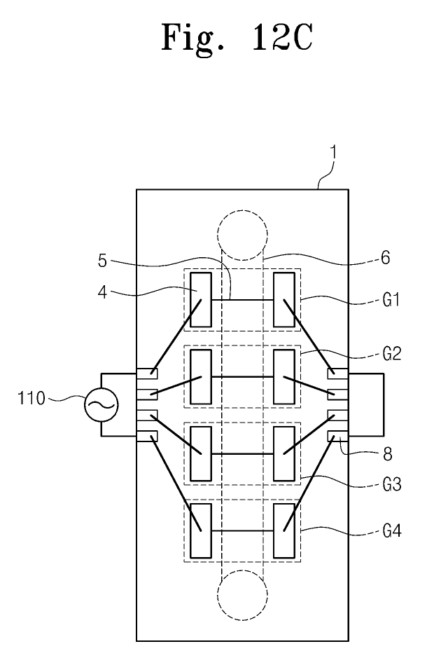

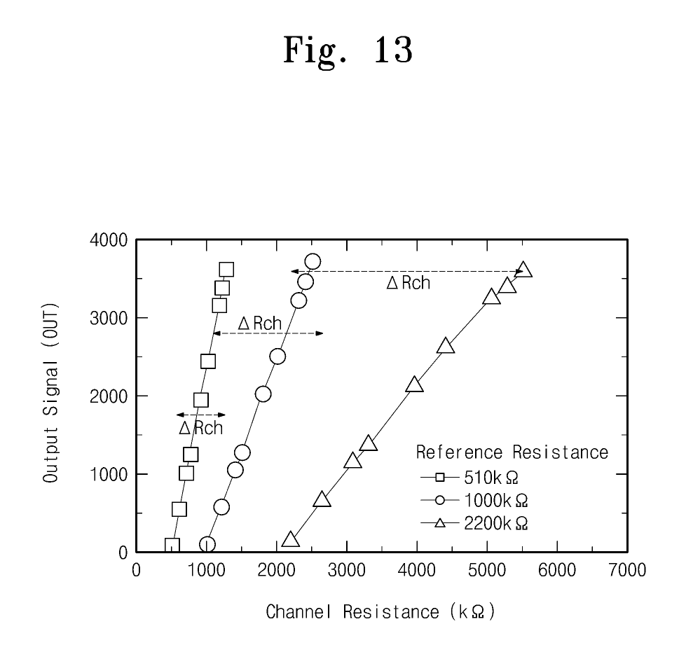

The reference resistance 121 has substantially the same resistance value as the initial resistance value of the probe channel of the biosensor, in order to sensitively detect an electrical conductivity change caused by the binding between the target material and the probe material. The reference resistance 121 may be a resistor in the analog circuit unit 120. Also, the reference resistance 121 may be the resistance in the probe channel that does not cause the binding between the target material and the probe material in the biosensor. This will be described later in detail with reference to FIGS. 12A to 12C.

The channel resistance 122 is the resistance in the probe channel where the target material and the probe material bind together. The channel resistance 122 is connected to the analog circuit unit 120 by attachment of the biosensor, and varies depending on the binding between the probe material and the target material in the biosensor.

In the analog circuit unit 120, by attachment of the biosensor, the reference resistance 121 and the channel resistance 122 may be connected in series to form a closed circuit. When the biosensor is attached, a voltage drop occurs across each of the reference resistance 121 and the channel resistance 122 in the analog circuit unit 120. A reference voltage across the reference resistance 121 and a channel voltage across the channel resistance 122 are inputted to the differential amplifier 123.

The differential amplifier 123 amplifies a difference between the reference voltage and the channel voltage. That is, the differential amplifier 123 amplifies a minute voltage difference changing when the target material and the probe material bind in the probe channel of the biosensor, and outputs the amplified voltage difference as a measurement signal. The measurement signal outputted from the differential amplifier 123 is processed through the amplifier 124 for adjustment to the input range of the ADC and the filter 124 for removal of a noise, and the resulting signal is inputted to the lock-in amplifier 125. The lock-in amplifier 125 outputs only a measurement signal, which has the same frequency as the reference signal received from the phase compensation circuit 126, so that only an analog signal having the same phase as the input signal may be provided to the ADC.

In this way, the analog signal outputted from the analog circuit unit 120, i.e., the measurement signal of the voltage variation of the biosensor is processed through the ADC, and the resulting signal is provided to the signal processing unit 200.

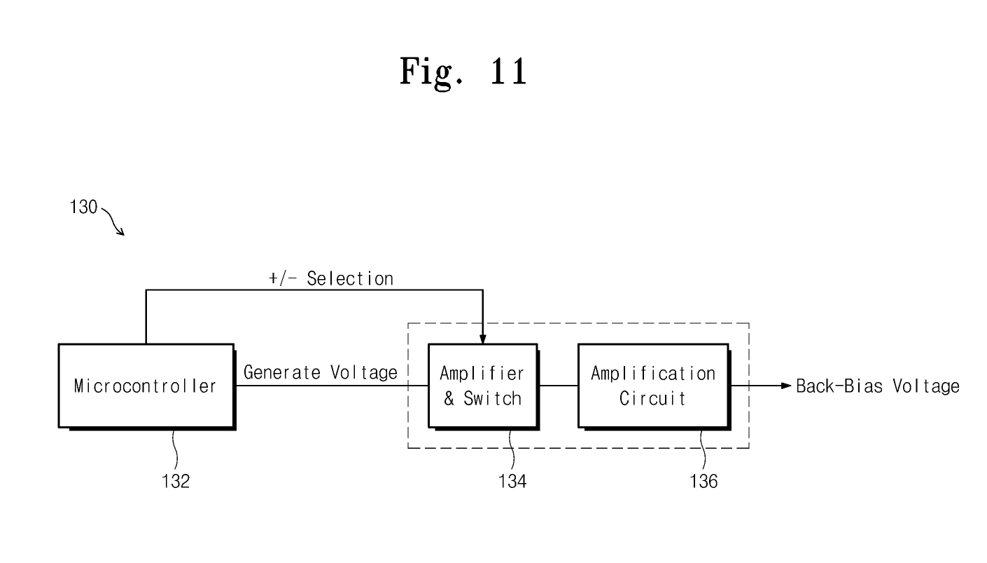

FIG. 11 is a block diagram of the back-bias voltage generating unit 130 in the measurement unit 100 of the biosensor reader system according to an exemplary embodiment of the present invention.

The back-bias voltage generating unit 130 generates a back-bias voltage applied to the substrate of the biosensor, in order to sensitively measure an electrical conductivity change in the probe channel of the biosensor. If the back-bias voltage is applied to the substrate of the biosensor, a great electrical conductivity change may be induced even by the electric field effect caused by the small charge quantity of the biomaterial according to the binding between the probe material and the target material. In the case of the FET biosensor using a semiconductor layer, when the impurity concentration of the probe channel is low, a great electrical conductivity change is caused even by a small charge quantity change. Herein, because the electrical conductivity change is maximized at the operating point of the maximum transconductance of the FET, the sensitivity of the biosensor may be increased by applying the back-bias voltage to the substrate of the biosensor.

Referring to FIG. 11, the back-bias voltage generating unit 130 includes a microcontroller 132, an amplifier/switch 134, and an amplification circuit 136.

The microcontroller 132 generates signals of various waveforms such as a sine wave, a pulse wave, and a DC voltage. The sine wave may be generated by a DAC in the microcontroller 132, and the pulse wave may be generated by a digital output signal of ‘1 ’ and ‘0’.

The signal outputted from the microcontroller 132 is processed through the amplifier/switch 134 and the amplification circuit 136, and the resulting signal is outputted as a back-bias voltage of about −24 V to about +24 V provided by the power supply unit 500.

FIGS. 12A to 12C are diagrams illustrating the electrical connection between the reference resistance and the probe channel in the measurement unit 100 of the biosensor reader system according to an exemplary embodiment of the present invention.

FIG. 12A illustrates the electrical connection between a channel resistance Rch of the biosensor 1 and a reference resistance Rf (see 121 of FIG. 10) of the analog circuit unit 120 of the biosensor reader system.

Referring to FIG. 12A, the probe channel 5 (i.e., the channel resistance Rch) of the biosensor 1 is connected in series to the reference resistance Rf of the analog circuit unit 120. The input signal generating unit 110, the reference resistance Rf, and the channel resistance Rch may form a closed circuit. The channel resistance Rch varies depending on the binding between the target material and the probe material. The reference resistance Rf may be a resistor having a fixed resistance value in order to accurately measure an electrical conductivity change in the probe channel 5 to which probe materials are immobilized. The fixed resistance value is electrical conductivity of the probe channel where the target material does not bind to the probe material. That is, the fixed resistance value is a voltage drop across the probe channel where the target material does not bind to the probe material.

When the input signal 110 is applied to the reference resistance Rf and the channel resistance Rch connected in series to each other, a predetermined voltage is applied to each of the channel resistance Rch and the reference resistance Rf. That is, a voltage drop occurs across each of the channel resistance Rch and the reference resistance Rf. The channel voltage across the probe channel 5 (i.e., the channel resistance Rch) of the biosensor 1 and the reference voltage across the reference resistance Rf of the measurement unit 100 are inputted to the differential amplifier 123 (see FIG. 10).

Accordingly, the voltage difference between the initial channel voltage of the probe channel 5 before the binding between the target material and the probe material and the measurement voltage after the binding between the target material and the probe material may be obtained as the measurement signal. Thus, a minute electrical conductivity change in the probe channel 5 caused by the binding between the target material and the probe material can be measured.

FIG. 12B illustrates the electrical connection between the probe channel and the reference resistance in one biosensor according to another exemplary embodiment of the present invention.

Referring to FIG. 12B, in the biosensor 1, first and second probe channels 5a and 5b are formed and first and second fluid channels 6a and 6b are formed corresponding respectively to the first and second probe channels 5a and 5b.

The same probe materials are immobilized to the first and second probe channels 5a and 5b, and different analysis solutions are supplied to the first and second fluid channels 6a and 6b. That is, an analysis solution containing target materials binding specifically to probe materials may be supplied to the first fluid channel 6a, and a buffer solution not containing target materials may be supplied to the second fluid channel 6b.

The first and second probe channels 5a and 5b may be connected in series by the common source/drain electrodes 4. Accordingly, the measurement voltage across the first probe channel 5a (i.e., the channel resistance Rch) and the reference voltage across the second probe channel 5b (i.e., the reference resistance Rf) may be inputted to the differential amplifier 123 (see FIG. 10) of the biosensor reader system. That is, in one biosensor 1, the reference resistance Rf and the channel resistance Rch connected in series can be implemented, and the voltage difference caused by the binding between the target material and the probe material can be measured.

When the analysis solution is supplied to the first fluid channel 6a, the channel voltage varies because the target material and the probe material bind in the first probe channel 5a. When the buffer solution is supplied to the second fluid channel 6b, the channel voltage does not vary because the target material and the probe material do not bind in the second probe channel 5b. That is, because the first probe channel 5a and the second probe channel 5b are fabricated through the same process for fabricating a semiconductor device, the electrical conductivities of the first probe channel 5a and the second probe channel 5b before the supply of the analysis solution are substantially the same as each other. Therefore, an electrical conductivity change caused by the binding between the target material and the probe material can be accurately measured from the difference between a voltage drop across the first probe channel 5a where the target material and the probe material bind together and a voltage drop across the second probe channel 5b where the target material and the probe material do not bind together.

FIG. 12C illustrates the electrical connection between the biosensor reader and the probe channel and the reference resistance in one biosensor 1 according to another exemplary embodiment of the present invention.

Referring to FIG. 12C, the biosensor 1 includes: a probe channel 5 to which probe materials are immobilized; a probe channel 5 to which probe materials are not immobilized; and a fluid channel 6 for supplying an analysis solution to the probe channels 5. When an analysis solution containing target materials is supplied simultaneously to the probe channel 5 to which probe materials are immobilized and the probe channel 5 to which probe materials are not immobilized, the biosensor reader can measure a voltage across each of the probe channels 5. In FIG. 12C, the probe channel 5 to which probe materials are immobilized may be a channel resistance with a variable resistance value, and the probe channel 5 to which probe materials are not immobilized may be a reference resistance with a fixed resistance value. That is, when the biosensor 1 is attached to the biosensor reader, a voltage drop may occur across each of the channel resistance and the reference resistance due to an input signal 110. Also, a voltage drop across the channel resistance may vary when an analysis solution is supplied to the fluid channel 6.

The biosensor 1 may analyze various target materials simultaneously. For example, the biosensor 1 may include: a first group G1 for analyzing a prostate-specific antigen (PSA); a second group G2 for analyzing an alpha-feto protein (AFP) for diagnosis of a liver cancer; and a third group G3 for analyzing a carcinoembryonic antigen (CEA) for diagnosis of a childhood cancer. Also, the biosensor 1 may further include a fourth group G4 for providing a reference value when measuring an electrical conductivity change caused by the binding between the target material and the probe material.

Each of the groups G1 to G4 may include a probe channel 5. Different probe materials are immobilized to the probe channels 5 of the first to third groups G1 to G3, while probe materials are not immobilized to the fourth group G4 providing the reference value. The source/drain electrodes 4 are connected across the probe channel 5 of each of the groups G1 to G4. Also, the source/drain electrodes 4 of the groups G1 to G4 may be connected through an electrode pad 8 to the measurement unit (see 100 of FIG. 8) of the biosensor reader system.

When the biosensor 1 is connected to the measurement unit 100 of the biosensor reader system, one of the first to third groups G1 to G3 and the fourth group G4 are connected in series to the measurement unit 100. That is, to measure an electrical conductivity change according to the binding between the target material and the probe material, the electrode pads 8 connected to the first to third groups G1 to G3 are selectively connected to the measurement unit 100, and the electrode pad 8 connected to the fourth group G4 is fixedly connected to the measurement unit 100. Accordingly, the measurement unit 100 can measure a channel voltage in the probe channel of the selected group and a reference voltage in the probe channel of the fourth group G4. Because the first to fourth groups G1 to G4 are fabricated through the same semiconductor process, the electrical conductivities in the first to fourth groups G1 to G4 before the supply of an analysis solution are substantially the same as one another. Therefore, when the analysis solution is supplied, an electrical conductivity change caused by the binding between the target material and the probe material can be accurately measured from the difference between a voltage drop across the probe channel 5 of the selected group (one of the first to third groups G1 to G3) where the target material and the probe material bind together and a voltage drop across the probe channel 5 of the fourth group G4 where the target material and the probe material do not bind together.

FIG. 13 is a graph illustrating the output waveform outputted from the measurement unit in accordance with the channel resistance of the biosensor in the biosensor reader system according to an exemplary embodiment of the present invention.

Referring to FIG. 13, the output signal outputted from the measurement unit is an analog signal that is obtained by amplifying an electrical conductivity variation caused by the binding between the target material and the probe material in the probe channel of the biosensor. That is, the output signal outputted from the measurement unit is a voltage signal that is obtained by amplifying the difference between a channel voltage across the channel resistance of the biosensor and a reference voltage across the reference resistance.

Referring to FIG. 13, the output signal of the measurement unit may have the following relationship.

Output Signal (OUT)=a×(Rch−Rref)/Rref+b, where ‘a’ and ‘b’ are constants, ‘Rch’ is a channel resistance, and ‘Rref’ is a reference resistance.

The output signal outputted from the measurement unit is proportional to a change in the channel resistance, and the measurement range varies depending on the resistance value of the reference resistance. That is, if the channel resistance has a large resistance value, the measurable channel resistance range ΔRch may be increased by setting the reference resistance to a large resistance value. For example, if an about 510 kΩ reference resistance is used, a variation ΔRch of an about 0.5 MΩ to about 1.5 MΩ channel resistance may be measured; and if an about 2.2 MΩ reference resistance is used, a variation ΔRch of an about 2.2 MΩ to about 5.5 MΩ channel resistance may be measured.

As described above, the biosensor reader and the biosensor reader system according to the present invention can more accurately measure the electrical conductivity variation caused by the binding between the target material and the probe material, by using the reference voltage across the reference resistance fixed at the initial resistance value of the probe channel. That is, the use of the biosensor reader and the biosensor reader system according to the present invention makes it possible to detect a small amount of target material within a body, such as cancer, cardiac infarction and DNA.

Also, the biosensor reader according to the present invention is small-sized and easy to carry, thus making it possible to quickly analyze the target material.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A biosensor reader that has a field-effect transistor (FET) biosensor, which includes between electrodes at least one probe channel to which probe materials are immobilized, attached thereto and analyzes an electrical conductivity change of the probe channel caused by the binding between the probe material and a target material contained in an analysis solution, the biosensor reader comprising:
a measurement module connecting the probe channel electrically to a reference resistance having a fixed resistance value by the attachment of the FET biosensor, measuring a reference voltage drop across the reference resistance and a channel voltage drop across the probe channel, and analyzing an electrical conductivity change of the probe channel from the reference voltage drop and the channel voltage drop; and
an output module outputting the analysis result of the target material according to the electrical conductivity change.

2. The biosensor reader of claim 1, wherein the fixed resistance value is an electrical conductivity of the probe channel where the target material does not bind to the probe material.

3. The biosensor reader of claim 2, wherein the FET biosensor includes a first and a second probe channels,
wherein the measurement module supplies the analysis solution to the first probe channel and a buffer solution to the second probe channel,
wherein measuring the reference voltage drop is measuring a voltage drop across the second probe channel.

4. The biosensor reader of claim 3, wherein the second probe channel provides the reference resistance.

5. The biosensor reader of claim 2, wherein the probe channel is provided in plurality and the probe materials are not immobilized to one of the probe channels,
wherein the measurement module commonly supplies the analysis solution to the probe channels,
wherein measuring the reference voltage drop is measuring a voltage drop across the probe channel to which probe materials are not immobilized.

6. The biosensor reader of claim 1, wherein the measurement module includes:
an attachment unit to which the FET biosensor is attached; and
a printed circuit board (PCB) connected to the electrodes of the FET biosensor and connected electrically to the probe channel of the FET biosensor.

7. The biosensor reader of claim 6, wherein the reference resistance is a resistor provided in the measurement module.

8. The biosensor reader of claim 6, wherein the measurement module further includes a cover unit adhering the FET biosensor and the PCB closely onto the attachment unit.

9. The biosensor reader of claim 1, further comprising a pump module supplying at least one analysis solution to the probe channel of the FET biosensor.

10. The biosensor reader of claim 9, wherein the pump module includes:
a plurality of storage containers storing the analysis solution; and
a plurality of syringe pumps supplying/discharging the analysis solution to/from the probe channel of the FET biosensor.

11. A biosensor reader system that has a field-effect transistor (FET) biosensor, which includes between electrodes a probe channel to which probe materials are immobilized, attached thereto and analyzes an electrical conductivity change of the probe channel caused by the binding between the probe material and a target material contained in an analysis solution, the biosensor reader system comprising:
a measurement unit measuring a channel voltage drop across the probe channel of the FET biosensor, whose resistance value varies by the binding between the target material and the probe material, and a reference voltage drop across a reference resistance with a fixed resistance value, and outputting a measurement signal according to a difference between the channel voltage drop and the reference voltage drop;
a signal processing unit analyzing the target material from the measurement signal; and
an output unit outputting the signal process result of the signal processing unit.

12. The biosensor reader system of claim 11, wherein the reference resistance has a resistance value of the probe channel where the target material does not bind to the probe material.

13. The biosensor reader system of claim 11, wherein the measurement unit includes:
an input signal generating unit providing an input signal to the electrodes of the FET biosensor to generate the channel voltage drop and the reference voltage drop; and
a differential amplifier amplifying the difference between the channel voltage drop and the reference voltage drop and outputting the amplified difference as the measurement signal.

14. The biosensor reader system of claim 11, wherein the measurement unit provides a resistor being the reference resistance connected in series to the electrodes of the FET biosensor.

15. The biosensor reader system of claim 11, wherein the reference resistance is provided from the FET biosensor.

16. The biosensor reader system of claim 15, wherein the reference resistance and the probe channel are connected in series to each other in the FET biosensor.

17. The biosensor reader system of claim 16, wherein the analysis solution and a non-analysis solution are supplied to the probe channel of the FET biosensor, and the measurement unit measures the reference voltage drop across a probe channel to which the non-analysis solution is supplied.

18. The biosensor reader system of claim 15, wherein the FET biosensor further includes a probe channel to which the probe materials are not immobilized and the analysis solution is supplied, and the measurement unit measures the reference voltage drop across the probe channel to which the probe materials are not immobilized.

19. The biosensor reader system of claim 11, wherein the signal processing unit includes a library file that has measurement data extracted from the measurement signal outputted from the measurement unit and library data obtained from an electrical conductivity change depending on the concentration of the target material.

20. The biosensor reader system of claim 19, wherein the signal processing unit calculates the concentration of the target material by comparing the measurement data extracted from the measurement signal with the library data obtained from the electrical conductivity change depending on the concentration of the target material.
